(19) United States
(12) Patent Application Publication
(10) Pub. No.: US 2022/0131016 A1
(43) Pub. Date: Apr. 28, 2022

(54) CHARGE BALANCED RECTIFIER WITH SHIELDING

(71) Applicant: SEMICONDUCTOR COMPONENTS INDUSTRIES, LLC, Phoenix, AZ (US)

(72) Inventor: Andrei KONSTANTINOV, Sollentuna (SE)

(73) Assignee: SEMICONDUCTOR COMPONENTS INDUSTRIES, LLC, Phoenix, AZ (US)

(21) Appl. No.: 16/949,394

(22) Filed: Oct. 28, 2020

(51) Int. Cl. H01L 29/872; H01L 29/16; H01L 29/06

(52) U.S. Cl. CPC H01L 29/872; H01L 29/0611; H01L 29/1608

(57) ABSTRACT

SiC Schottky rectifiers are described with a Silicon Carbide (SiC) layer, a metal contact, and an n-type channel region disposed between the SiC layer and the metal contact. A p-pillar may be formed adjacent to the metal contact and extending in a direction of the SiC layer, and a a p-type shielding body adjacent to the metal contact and extending from the metal contact in a direction of the SiC layer. The SiC Schottky rectifiers may include a first channel region of the n-type channel region having a first n-type doping concentration, and disposed between the p-pillar and the p-type shielding body, the first channel region being adjacent to the metal contact. The SiC Schottky rectifiers may include an n-pillar providing a second channel region of the n-type channel region and having a second n-type doping concentration that is lower than the first n-type doping concentration in the first channel region, the n-pillar being disposed adjacent to the first channel region, and to the p-pillar.

### TECHNICAL FIELD

This description relates to Schottky rectifier semiconductor devices.

### BACKGROUND

Silicon carbide (SiC) power devices provide advantages such as high switching speed and low power losses. Examples of highly-efficient SiC power devices include (but are not limited to) majority-carrier components, such as Schottky rectifiers and field-effect transistors (FETs).

Schottky rectifiers are types of diodes with a metal-semiconductor junction. Schottky rectifiers are known to have a low forward voltage drop, and fast switching speeds. SiC Schottky rectifiers thus provide the advantages of SiC devices in general, as well as the advantages of conventional (e.g., silicon-based) Schottky rectifiers. However, SiC Schottky rectifiers may exhibit undesirably high leakage currents, and low breakdown voltages.

### SUMMARY

In the following disclosure, example implementations of a Schottky rectifier are described, including a Silicon Carbide (SiC) epitaxial layer formed on a low-resistivity n-type SiC substrate layer. A metal contact may be provided on a surface of the SiC epitaxial layer. An array of n-type and p-pillars may be included in the SiC epitaxial layer. The metal contact may form a Schottky barrier to the n-pillars included in the SiC epitaxial layer, and a contact to the p-pillars included in the SiC epitaxial layer. An Ohmic contact may be provided to an opposed surface of the substrate layer.

The array of n-type and p-pillars included in the SiC epitaxial layer may extend at least a majority of a thickness of the SiC epitaxial layer between the substrate layer and the metal contact of the Schottky rectifier. The n-type and p-pillars may be doped, and spaced laterally, to achieve a charge balance therebetween in which electrical charge of non-compensated donors in the n-pillars is substantially similar to that of non-compensated acceptor charge of the p-pillars. In some example implementations, the n-pillars may extend an entire distance between the layer substrate to a surface of the SiC epitaxial layer adjacent to the metal contact of the Schottky rectifier. In some example implementations, the p-pillars may extend from the surface of the SiC epitaxial layer adjacent to the metal contact of the Schottky rectifier over at least a majority of the thickness of the SiC epitaxial layer in a direction of the substrate layer, as referenced above, or, in alternate implementations, may extend an entire distance from the surface of the SiC epitaxial layer adjacent to the metal contact of the Schottky rectifier to the substrate layer. Such p-pillars may be referred to as deep p-pillars.

An additional array of shallow shielding p-bodies may be further provided adjacent to the metal contact of the Schottky rectifier. Such shallow shielding p-bodies may be provided with a much higher doping than the deep p-pillars. The doping of said shallow shielding p-bodies may be selected high enough to maintain the shallow shielding p-bodies in a mostly non-depleted state, even at a highest reverse bias to be applied to the Schottky rectifier. The shallow shielding p-bodies may be arranged to have a shorter period (or shorter pitch) than the deep p-pillars. A portion of the n-pillars adjacent to the metal contact of the Schottky rectifier may be further provided with a higher doping than a remainder of the n-pillars, up to approximately a depth of the shallow shielding p-bodies.

According to one general aspect, a Schottky rectifier device may include a Silicon Carbide (SiC) layer, a metal contact, and an n-type channel region disposed between the SiC layer and the metal contact. The Schottky rectifier device may include a p-pillar adjacent to the metal contact and extending in a direction of the SiC layer, and a p-type shielding body adjacent to the metal contact and extending from the metal contact in a direction of the SiC layer. The Schottky rectifier device may include a first channel region of the n-type channel region having a first n-type doping concentration, and disposed between the p-pillar and the p-type shielding body, the first channel region being adjacent to the metal contact, and an n-pillar providing a second channel region of the n-type channel region and having a second n-type doping concentration that is lower than the first n-type doping concentration in the first channel region, the n-pillar being disposed adjacent to the first channel region, and to the p-pillar.

According to another general aspect, a Schottky rectifier device may include a metal contact, an n-type SiC substrate, an epitaxial layer disposed on the n-type SiC substrate, an array of n-pillars disposed within the epitaxial layer, and an array of p-pillars disposed within the epitaxial layer, each p-pillar of the array of p-pillars being adjacent to an n-pillar of the array of n-pillars. The Schottky rectifier device may include an array of p-type shielding bodies formed adjacent to the metal contact and having a lateral spacing from the p-pillars, and n-type channel regions formed within the epitaxial layer and within the lateral spacing, the n-type channel regions having a first n-type doping concentration higher than a second n-type doping concentration of the array of n-pillars.

According to another general aspect, a method of making a Schottky rectifier device may include forming a Silicon Carbide (SiC) substrate layer, forming an n-type epitaxial region on the SiC substrate, and performing p-type ion implantation to form a p-pillar. The method may include forming an implanted n-type region across a surface of the n-type epitaxial region, forming a p-type shielding body in the implanted n-type region, and forming a metal contact on the p-pillar, the n-type region, and the p-type shielding body.

The details of one or more implementations are set forth in the accompanying drawings and the description below. Other features will be apparent from the description and drawings, and from the claims.

### BRIEF DESCRIPTION OF THE DRAWINGS

FIG. 1 is a schematic cross-section of a charge balanced SiC Schottky rectifier with shielding.

FIG. 2 shows a vertical profile of an electric field in the SiC Schottky rectifier of FIG. 1, compared to the profile in a device without the shallow, shielding p-type bodies.

FIG. 3 is a graph illustrating a forward drop for an implementation of the SiC Schottky rectifier of FIG. 1, compared to that of a device without the shallow, shielding p-type bodies.

FIG. 4 is a graph illustrating leakage current through a Schottky barrier to n-type SiC as a function of electric field at the barrier surface.

FIG. 5 is a schematic cross-section of a charge balanced SiC Schottky rectifier with multiple shallow, shielding p-bodies providing shielding.

FIG. 6A is a schematic cross-section of an alternate embodiment of a charge-balanced SiC Schottky having a hexagonal unit cell.

FIG. 6B is a top view of the example embodiment of FIG. 6A.

FIG. 7 is a top view of another example embodiment of FIG. 1, illustrating a power rectifier having an array of unit cells shown in cross section in FIG. 1.

FIGS. 8A-8H illustrate operations for forming the Schottky rectifier device of FIG. 1.

### DETAILED DESCRIPTION

Performance of majority-carrier devices can potentially be improved utilizing the concept of charge balance, in which the charges of closely-space pillars of donors and acceptors compensate each other. Such a charge-balanced power device can potentially have lower on-state resistance and higher breakdown voltage than a conventional planar device. Charge-balanced silicon MOSFETs are widely used in power conversion, and offers potential advantages for Silicon Carbide (SiC) devices, as well.

For example, the charge balance design can be also applied to SiC Schottky rectifiers. Charge-balanced Schottky rectifiers, formed using a metal-semiconductor interface, are typically not implemented in silicon power device technology. Moreover, design requirements of a SiC Schottky rectifier are different in many aspects from that of a silicon charge-balanced MOSFET. For example, the critical field in SiC is approximately ten times higher than in silicon, and exposure of the Schottky metal to such high electric field can cause significant reverse leakage. Such reverse leakage is increased when a low barrier height of the Schottky metal is used to achieve low rectifier turn-on voltage in forward bias. Therefore, it is not feasible to easily translate optimum design of a classical charge-balanced silicon device to that of a charge-balanced SiC Schottky rectifier.

In the present description, a SiC Schottky rectifier with charge balanced design is implemented by including shallow shielding bodies, which mitigate the above-referenced effects of the typically-high critical field in SiC Schottky rectifiers. For example, the shallow shielding bodies reduce reverse leakage currents during reverse bias, while still enabling low rectifier turn-on voltage and low on-resistance in forward bias, as well as enabling fast switching. As also described, the shallow shielding bodies may block a portion of a current path of the SiC Schottky rectifier, but additional channel doping may be provided in a region of the shallow shielding bodies to mitigate any associated, extra resistance that may occur as a result of such blocking.

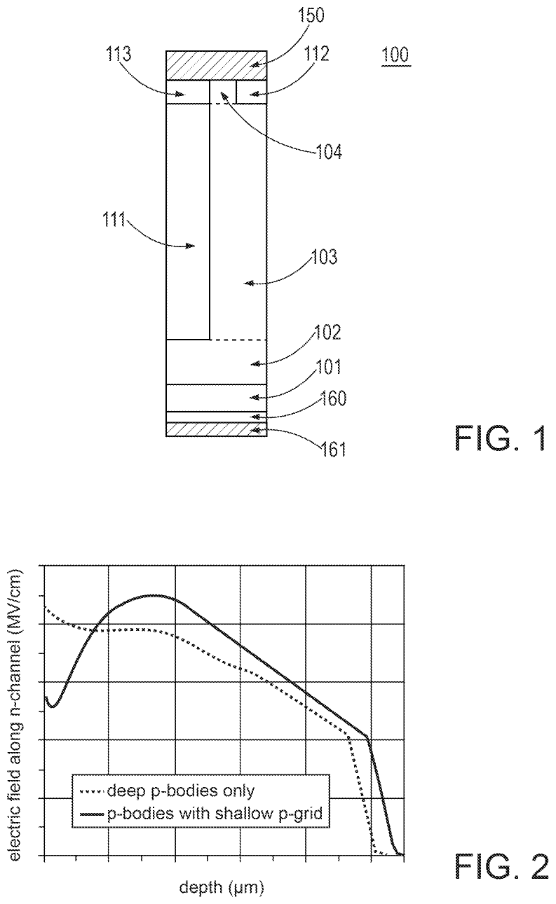

FIG. 1 is a schematic cross-section of a charge balanced SiC Schottky rectifier 100 with shielding. FIG. 1 illustrates half of a unit cell, which has a second, symmetrical half that is not illustrated in FIG. 1. Multiple such unit cells may be used for form an array of unit cells within an active area, and a p-type rim and a termination region may be formed around a periphery of the active area, in order to prevent excessive electric field and early breakdown in the device periphery.

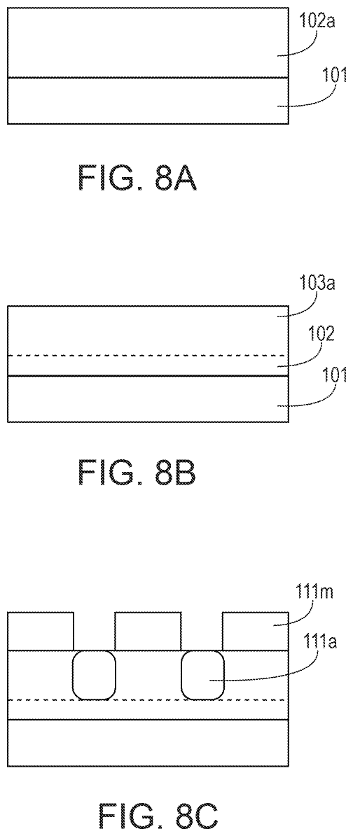

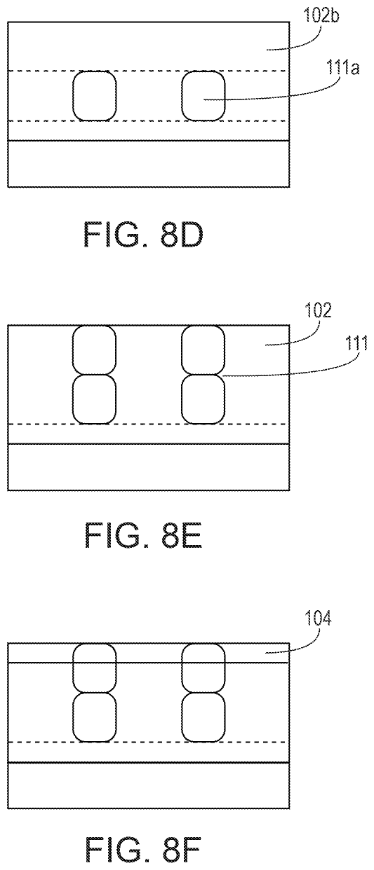

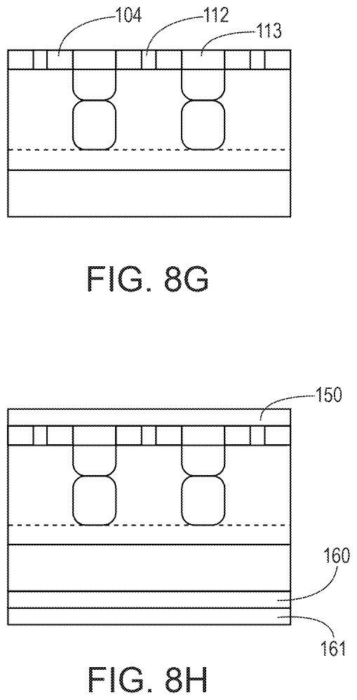

In FIG. 1, a substrate 101 may be formed using, e.g., a single crystal SiC substrate, of, also by way of example, a 4H polytype. Multiple doped regions 102, 103, 104, 111, 112, and 113 are formed in an epitaxial layer formed on the substrate 101, as shown in FIGS. 8A-8H (e.g., layer 102a of FIG. 8A).

Regions 102 and 103 form an n-type drift region. The regions 102 and 103 (with region 104) provide a current channel region in a forward bias. Presence of the n-type drift region 102, 103 also blocks desired reverse bias.

Region 103 also represents an n-type pillar, or n-pillar, while region 111 represents a p-type pillar, or p-pillar, also referred to as a p-body, that is charge-balanced with respect to the n-pillar 103. As explained in more detail, below, the Schottky-barrier rectifier 100 is provided with a charge balance of acceptors in the p-pillar 111 and of the donors in the n-pillar 103. Such a charge balance may be understood to mean that the total charges of non-compensated acceptors and donors in respective p-type and n-type regions are substantially close in number. Such charge balance enables desirably low forward voltage and on resistance, with desirably high reverse blocking performance (and correspondingly low leakage currents).

In some implementations, the charge-balanced p-body, or p-pillar, 111 may extend over a majority of the drift region 102/103. Region 102 represents a charge-unbalanced portion of the drift region 102, 103, i.e., a portion located beneath a lowest point of the p-pillar 111. Such a charge-unbalanced region 102 may represent a relatively small part of the drift region 102, 103 thickness, e.g., less than half, or less than one-fourth of a total thickness of the drift region 102, 103. In some implementations, the p-pillar 111 may extend to the substrate 101, in which case the charge-unbalanced region 102 is not included.

Regions 112 and 113 represent shallow shielding p-bodies, referred to as p-type shielding body 112 and p-type shielding body 113. In example implementations, the regions 112, 113 may be heavily-doped by acceptors, e.g., by Aluminum (Al). Example acceptor doses in the regions 112, 113 may be above 1×10¹⁸ cm⁻². As referenced above, SiC Schottky rectifiers typically experience a high critical electric field at a metal-semiconductor interface. In the example of FIG. 1, however, a metal layer 150 of the SiC Schottky rectifier 100 interfaces with n-type semiconductor region 104, which has a reduced area due to the presence of the regions 112, 113. For example, in FIG. 1, the region 104 has a reduced surface area as compared to a cross-sectional area of the region 103. The regions 112, 113 thus cause a metal-semiconductor interface to occur only at the interface between the metal layer 150 and the region 104, and thereby provide efficient shielding of the metal-semiconductor interface from a high electric field.

In the example of FIG. 1, the region 104 thus forms a first channel region, while the charge-balanced region (n-pillar) 103 forms a second channel region, and the charge-unbalanced region 102 forms a third channel region, of an entire n-type channel region 102, 103, 104. As an area of the first channel region 104 is reduced relative to that of the second channel region of the n-pillar 103 by the presence of the shallow p-type shielding body 112, 113 (e.g., as the n-pillar 103 is at least partially adjacent to the p-type shielding body 112), a resistance of the first channel region 104 may be commensurately higher than a resistance of the second channel region within the n-pillar 103.

To compensate for such increased resistance, the first channel region 104 may be provided with a higher donor (n-type doping) concentration than the second channel region of the n-pillar 103. For example, the first channel region 104 may be provided with a higher n-type doping concentration than the second channel region of the n-pillar 103 by a factor of between 1.5 and 5.

Electrical connection of the metal 150 to the shielding p-bodies 112, 113 may be by tunnel contact. For example, the near-surface portions of 112 and 113 may be provided with degenerate acceptor doping. In alternate embodiments, dedicated Ohmic contacts may be formed in the p-type shielding bodies 112, 113, e.g., by formation of the contact silicide.

Further in FIG. 1, an Ohmic contact 160 may be provided to a surface of the SiC substrate 101 opposite the surface adjacent to the charge-unbalanced region 102, and may represent the anode of the SiC Schottky rectifier 100. Solderable contact metal 161 may be disposed to an opposing surface of the Ohmic contact 160, e.g., as a stack of Titanium (Ti), Nickel (Ni), and Silver (Ag). The topside metal 150 may represent a metal stack, for example a stack of Ti, Titanium Nitride (TiN) and Al that are sequentially deposited onto the surface of SiC. In such embodiments, Ti forms a Schottky barrier to n-type SiC, TiN forms a diffusion barrier, and Al provides a power metal, e.g., for attaching wirebonds and for uniformly spreading current over a topside metal pad of the SiC Schottky rectifier 100. Alternately, the Schottky-barrier material may be Tantalum (Ta) or an alloy of Ti and TiN, or tungsten silicide (WSi). Ta, Ti—TiN alloys, and WSi form a Schottky barrier with a lower barrier height to n-SiC than Ti, which will result in a lower turn-on voltage.

As referenced above, lower turn-on voltage is desirable from the viewpoint of decreasing forward-bias power losses of a Schottky rectifier, but also tends to increase the barrier leakage under reverse-bias conditions. Reverse-bias leakage of a Schottky barrier to SiC rapidly increases with increasing the electric field at the Schottky interface. In FIG. 1, the Schottky-barrier SiC rectifier 100 is effectively shielded from such excessively high field by the inclusion of the heavily doped, shallow shielding p-bodies 112 and 113. As also described, a resulting narrowed width of the first channel region 104 may result in increased resistance of the SiC Schottky rectifier 100 during forward bias, but in FIG. 1 this effect is mitigated by increased donor (electron) concentration in the first channel region 104, as compared to the second channel region of the n-pillar 103.

Thus, FIG. 1 illustrates an example implementation(s) including the Silicon Carbide (SiC) layer 101, the metal contact 150, and the channel region 102, 103, 104 of a first conductivity type (e.g., n-type channel region) disposed between the SiC layer 101 and the metal contact 150. The region 112 forms a shielding body of a second conductivity type (e.g., p-type), the p-type shielding body 112 being adjacent to the metal contact 150 and extending from the metal contact 150 in a direction of the SiC layer 101. The p-type shielding body 113 thus forms a second body of the second conductivity type, the p-type shielding body 113 being adjacent to the metal contact 150 and extending from the metal contact 150 in the direction of the SiC layer 101. In FIG. 1, the p-pillar 111 includes the p-type shielding body 113 and extends in the direction of the SiC layer 101 (e.g., extends at least thirty percent of a distance from the metal contact 150 to the SiC substrate layer 101, as described herein).

The region 104 forms a first channel region of the n-type channel region 102, 103, 104, having a first doping concentration of the first conductivity type (e.g., n-type), and disposed between the p-type shielding body and the p-type shielding body 113, the first channel region 104 being adjacent to the metal contact 150. Then, the n-pillar 103 forms a second channel region of the n-type channel region 102, 103, 104, having a second doping concentration of the first conductivity type that is lower than the first doping concentration of the first conductivity type in the first channel region 104, the second channel region of the n-pillar 103 being disposed adjacent to the first channel region 104 and to the p-pillar 111.

Specifically, for example, the p-pillar 111 and the second channel region of the n-pillar 103 may provide the charge balanced effects described herein, while the region 102 provides a third channel region representing a charge-unbalanced channel region. With respect to the charge balancing of the p-pillar 111 and the second channel region of the n-pillar 103, a width and doping of each pillar 111, 103 may be maintained at a substantially low level, so as ensure the possibility of full pillar depletion without avalanche breakdown (except, as described, the near-surface region 113 of the p-pillar 111 may be provided with higher acceptor doping to form the p-type shielding body 113).

To further quantify a nature of the charge balancing between the p-pillar 111 and the second channel region of the n-pillar 103, an average lateral donor charge Q_{d} of non-compensated donors in the charge balanced n-pillar 103 may be defined. The average donor charge Q_{d} may be defined as a total amount of non-compensated donors in the second channel region 103, divided by the unit cell area. Similarly, acceptor charge Qₐ may be defined as a number of non-compensated acceptors in the p-pillar 111, divided by the unit cell area. Then, in example implementations, donor charge Q_{d} and acceptor charge Qₐ may have a deviation (e.g., a charge imbalance) of no more than around 1×10¹³ cm⁻². In some implementations, a charge imbalance of greater than 1×10¹³ cm⁻²may deteriorate reverse blocking performance, and result in premature avalanche breakdown (e.g., avalanche breakdown below a desired blocking voltage).

Although FIG. 1 illustrates half of a symmetrical unit cell, it will be appreciated, as referenced above and illustrated below in more detail with respect to FIGS. 6A, 6B, and 7, the SiC Schottky rectifier 100 of FIG. 1 may be implemented as part of an array of such devices (unit cells). Thus, the shallow, shielding p-bodies 112, 113 may be understood to be part of an array or grid of such bodies, having a period (pitch) that is smaller than a period of the p-pillar 111 (e.g., ½ or ⅓ thereof).

The charge balanced SiC Schottky rectifier 100 of FIG. 1 may also have design requirements related to a lateral component of the electric field that occurs, e.g., between the p-pillar 111 and the n-pillar 103. For example, if the n-pillar 103 is too wide and/or contains excessive donors, the lateral electric field component may cause early breakdown. Similar comments apply to the doping of the p-pillar 111. In some implementations, a product of p-pillar 111 width (referred to as “Wp”) times its non-compensated acceptor concentration (referred to as “P111”) should not exceed approximately 1×10¹³ cm⁻² (Wp*P111<1×10¹³ cm⁻²) in order to avoid the above-referenced early breakdown due to the lateral electric field. In example implementations, the SiC Schottky rectifier 100 might employ a p-pillar 111 with a length of approximately 2.5 μm or more, whereas a p-type shielding body 112 may have a depth of approximately between 200 nm and 800 nm, or more. For example, the p-type shielding body 112 may be no more than one-third of a length of the p-pillar 111.

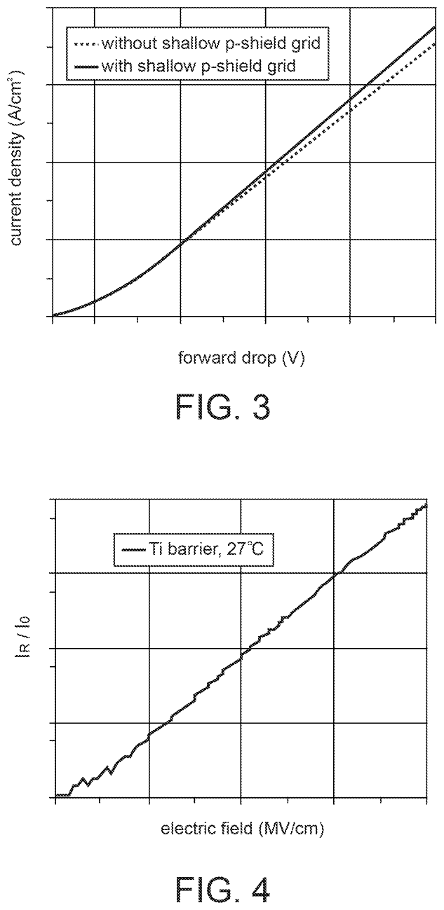

FIGS. 2 and 3 are graphs illustrating results of comparative simulations of implementations of the SiC Schottky rectifier 100 of FIG. 1, with and without shallow p-type bodies 112 and 113. FIG. 4 is a graph illustrating leakage current through a Schottky barrier to n-type SiC.

More specifically, FIG. 2 shows a vertical profile of an electric field in the SiC Schottky rectifier of FIG. 1, compared to the profile in a device without the shallow, shielding p-type bodies. For example, the electric field profile may extend up to 2.5 mV/cm or more, measured over a depth of 5-6 microns or more.

FIG. 3 illustrates a forward voltage drop, e.g., up to 2V or more, and associated current density over a range of, e.g., 2000 A/cm² or more, for an implementation of the SiC Schottky rectifier of FIG. 1, compared to that of a device without the shallow, shielding p-type bodies.

FIG. 4 is a graph illustrating leakage current through a Schottky barrier to n-type SiC as a function of electric field at the barrier surface. For example, a leakage current ration I^{R}/I⁰ may be determined over a range of, e.g., 107-1011, for corresponding electric field values up to 2.5 MV/cm, or more.

FIGS. 2 and 3 illustrate that both simulated devices demonstrate almost identical values of avalanche breakdown voltage. In the examples, the addition of the grid of p-type bodies 112 and 113 marginally increases the on-state resistance. However, the peak electric field at the Schottky metal layer (e.g., 150 in FIG. 1) is shown to decrease by, e.g, about 40%, e.g., from 2.3 MV/cm to 1.4 MV/cm. This results in a significant decrease of leakage current.

In the graph of FIG. 4, illustrating a plot of leakage current through a parallel-plane Ti Schottky barrier to an n-type SiC channel region, reverse current is plotted normalized to classical Richardson emission current, obtained from forward-bias measurements, using I₀=I_{F}*e^{(-qV}^{_{F}}^{/kT)}, where I_{F} is the forward bias, V_{F} is the forward voltage drop, k is the Boltzmann constant, and T is the temperature in Kelvin.

FIG. 4 illustrates that the reverse leakage may be many orders of magnitude higher than the classical Richardson-emission current, and its value is rapidly increasing with applied electric field. The above-referenced decrease of electric field at the metal gate (e.g., by 40%, or 0.9 MV/cm) will result in such examples in more than a 3 order-of-magnitude decrease of reverse leakage. Such a decrease in reverse leakage is particularly beneficial for the Schottky barriers with decreased barrier height, such as those formed on SiC by Ta, by Ti—TiN alloys or by WSi.

In some implementations, different manufacturing techniques may be used, which may include different trade-offs between, e.g., process costs and the various features and advantages described herein. For example, in example implementations, formation of heavily doped p-type shielding bodies 112 and 113 may involve hot implantation of Al acceptor ions at a temperature of 200 C or higher. In other example implementations, ion implantation at room temperature might be implemented, and may have a lower process cost.

Similarly, implemented doses of p-type doping in the shallow, shielding p-type bodies 112, 113 may be varied. An example rectifier may be obtained with a total Al dose in the shallow, shielding p-type bodies 112, 113 of above approximately 3×10¹³ cm⁻². In some implementations, the heavily doped, p-type shielding body 113 is not formed (e.g., omitted from the SiC Schottky rectifier 100 of FIG. 1), because, for example, shielding of the interface of n-type SiC 104 to the Schottky metal 150 can be provided by the charge-balanced p-pillar 111.

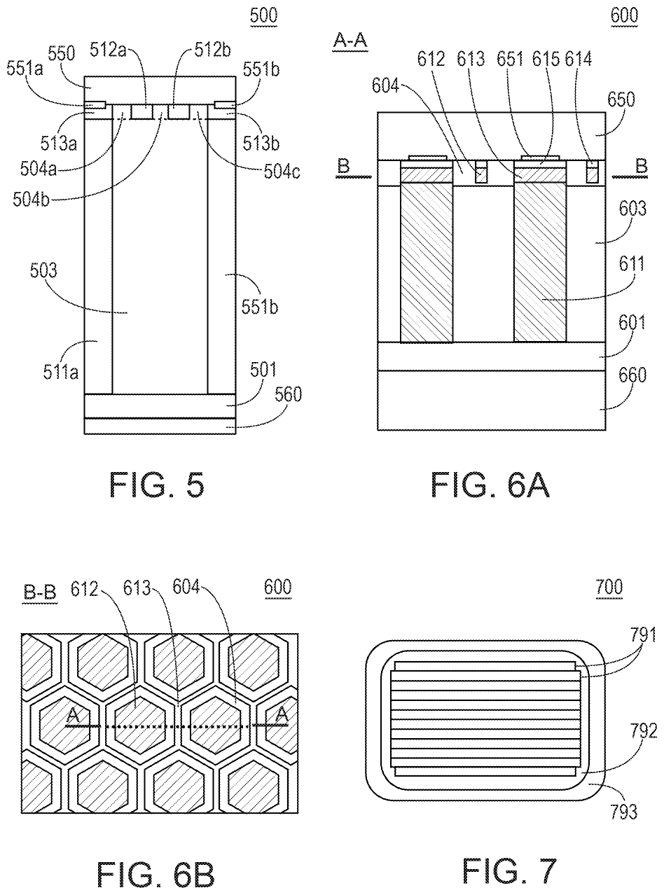

FIG. 5 is a schematic cross-section of a charge balanced SiC Schottky rectifier with multiple shallow, shielding p-bodies providing shielding, e.g., metal shielding. In FIG. 5, similar to FIG. 1, a unit cell 500 includes a SiC substrate layer 501, a n-type drift region of an n-pillar 503, and a charge-balanced p-pillar regions 511a, 511b. That is, due to a symmetry axis of the illustrated unit cell 500, along the drift region 503, in FIG. 5 a single p-pillar appears to be split between regions 511a and 511b. Put another way, the p-pillar region 511a and 511b both belong to physically the same p-pillar, but appear separately because of the referenced translational symmetry.

The doping N_{d} of the n-type drift region 503 may be chosen to be between 1.5 to 20 times a theoretical value for maximum doping No of a parallel-plane junction device in SiC, which value (V_{b0}) is limited by the critical field of avalanche breakdown, which may be expressed, for example, as V_{b0}=1720(N₀/1e16)^{0.8}.

Example numbers for doping of the drift-region 503 may be chosen as high as possible, given the charge balance is maintained, e.g., that Q_{d} and Qₐ are substantially close values as described herein. In other example implementations, a rectifier with high ratio of N_{d}/N₀ may be difficult to implement in manufacturing environment, because accurate charge balance is more difficult to maintain for a high ratio of N_{d}/N₀. A deviation from exact charge balance Q_{d}=Qₐ by more than approximately 1×10¹³ cm⁻² will decrease the blocking voltage.

Shallow shielding p-bodies 512a and 512b are formed next to the surface of metal contact 550, adjacent to the drift region, n-pillar 503. Shallow shielding p-bodies 512a and 512b may have an acceptor dose of 1×10¹⁴ cm⁻² or higher, and example depths of between approximately 0.2 μm and 1 μm. Heavily doped shielding body (portions) 513a and 513b are formed over a portion of charge-balanced p-pillar 511a/511b.

In the example of FIG. 5, a dedicated Ohmic contact 551a/551b may be formed on top of p-pillar 511a/511b, so as to decrease a forward drop of the SiC Schottky rectifier 500 in the surge-current mode. In this way, a ruggedness of the SiC Schottky rectifier 500 may be increased with respect to a surge-current event. Further, a near-surface portion of shielding p-bodies 513a/513b may be formed with degenerately high concentration of Al dopants, e.g., over 1×10²⁰ cm⁻³, which degenerate concentration will further decrease the resistance between the topside metal contact 550 and the p-type SiC shielding bodies 513a/513b. The top metal 550 will further provide a Schottky contact to vertical channel regions 504a, 504b, and 504c. An Ohmic contact 560 is arranged at a back side of the n-type SiC substrate layer 501.

FIG. 6A is a schematic cross-section of an alternate embodiment of a charge-balanced SiC Schottky having a hexagonal unit cell. FIG. 6B is a top view of the example embodiment of FIG. 6A.

In FIGS. 6A and 6B, the SiC Schottky rectifier 600 is formed on SiC substrate layer 601. An n-pillar 603 provides an n-type drift region that is charge-balanced with respect to p-pillar 611. Shielding p-bodies 612 are provided in the drift regions, n-pillars 603, e.g., provided above a center line of the of the drift regions, n-pillars 603.

Shielding p-bodies 613 are also provided, which have doping and thickness close to that of shielding p-bodies 612. Degenerately doped p-type regions 614 and 615 are provided next to the SiC surface at the metal contact 650, and Ohmic contacts are provided using regions 615. The topside metal 650 forms a Schottky contact to the vertical channel regions 604.

A device top view is shown, for the cross-section along line B-B, in FIG. 6B. The line B-B intersects regions 604, 612 and 613. As seen from FIG. 6B, the SiC Schottky rectifier 600 has a cellular hexagonal layout. Also shown in FIG. 6B is the line A-A, along which the cross-section shown in FIG. 6A is taken.

The example layout of the SiC Schottky rectifier 600 shown in FIG. 6B has full hexagonal symmetry. In other examples, e.g., in specific applications, the symmetry may form elongated polygons, including, e.g., providing rounding at the polygon corners.

FIG. 7 is a top view of another example embodiment of FIG. 1, illustrating a power rectifier having an array of unit cells 791, shown in cross section in FIG. 1. The SiC Schottky rectifier 700 is further provided with a p-body 792 forming a continuous p-type rim along the periphery of the array of unit cells 791. Junction termination region 793 may further be provided along the periphery of the p-body rim 792. An outer periphery of regions 792 and 793 may be provided with rounded corners, in order to avoid electric field concentration. The same or similar arrangement of regions 792 and 793 may be applied if the unit cell has a cellular rather than linear structure, such as that shown in FIGS. 6A and 6B.

FIGS. 8A-8H illustrate operations for forming the Schottky rectifier device 100 of FIG. 1. In FIG. 8A, an n-type epitaxial region 102a is formed on a single crystal SiC substrate 101, e.g., of 4H polytype crystal modification. In FIG. 8B, implantation of donor ions is then performed in order to achieve desired doping of regions 102 and 103a. Donor ion implant may be, e.g., either blanket (i.e. over entire wafer) or masked.

A mask layer 111m may then be deposited and patterned using photolithography, as is shown in FIG. 8C. The mask 111m may be any suitable material, such as photoresist, or silicon dioxide, or silicon nitride, or a metal. Acceptor ions are then implanted to form the lower portion of the charge-balanced p-pillars 111a, as is shown in FIG. 8C. An example acceptor for SiC is Aluminum. Boron and Gallium may also be used to perform p-type doping of p-pillar 111, either alone or in combination with Al. The implantation mask 111m is then stripped off, or otherwise removed from, the SiC wafer to continue the process.

Epitaxial regrowth is then performed, as shown in FIG. 8D, to form a topside SiC layer 102b. The cycles of ion implantation shown in in FIGS. 8B and 8C are then reiterated to obtain the structure shown in FIG. 8E, e.g., until p-pillars 111 are formed to a desired thickness, e.g., repeated until the p-pillars 111 reach a specified thickness.

Subsequently, implanted n-type regions 104 are formed, as shown in FIG. 8F. Heavily doped shielding p-bodies 112 and 113 are then formed, e.g., by hot implant of Al ions, as shown in FIG. 8G. For example, hot implant at a temperature of between approximately 200 C and 600 C may be used for doping SiC at high concentration, since, e.g., conventional room-temperature implant may result in undesirable amorphization of SiC. High-temperature anneal at a temperature between approximately 1500 C and 1800 C may then be performed, to activate implanted impurities. The resulting structure is shown in FIG. 8G. Fabrication may be concluded by formation of the topside metal contact 150, the backside Ohmic contact 160, and of solderable metal 161, as it is shown in FIG. 8H.

In some implementations, a SiC wafer may be thinned by mechanical grinding to minimize Ohmic and thermal resistance due to the substrate thickness. The backside contact may be formed by laser annealing of deposited Ni and Ti in order to form Ohmic nickel silicide contact 160. The use of Ti in the backside Ohmic metal stack may be beneficial for gettering excessive carbon upon formation of nickel silicide from SiC and Nickel during the pulsed laser anneal. Without appropriate carbon gettering the adhesion of layer 161 to the Ohmic contact 160 might be insufficient for reliable operation of diode 100 in a power conversion circuit.

Total SiC chip thickness may be between approximately 60 microns and 300 microns with the process equipment and technologies available at this point of time, however the possibility for manufacturing thinner SiC rectifiers are anticipated. Minimum SiC chip thickness is limited by the ratio of anticipated blocking voltage to the critical field of SiC. The rectifier chip thickness may thus be formed a close as possible to this ratio, which thus determines the minimum theoretical SiC thickness in a rectifier.

The manufacturing sequence shown in FIGS. 8A through 8H shows one cycle of epitaxial regrowth and two cycles of implantation for regions 111 and 103. A larger number of cycles of epitaxial regrowth and ion implantation such as those shown in FIGS. 8D and 8E may be required for certain applications, particularly if a blocking voltage of 1200V or higher is required. Desired thickness of a regrown layer such as that shown as region 102b may be limited by the penetration depth of acceptor and donor ions available with the process tools applied. An example value of thickness of regrown epitaxial layer is between approximately 500 nm and 3 microns.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments.

What is claimed is:

1. A Schottky rectifier device, comprising:
a Silicon Carbide (SiC) layer;
a metal contact;
an n-type channel region disposed between the SiC layer and the metal contact;
a p-pillar adjacent to the metal contact and extending in a direction of the SiC layer;
a p-type shielding body adjacent to the metal contact and extending from the metal contact in a direction of the SiC layer;
a first channel region of the n-type channel region having a first n-type doping concentration, and disposed between the p-pillar and the p-type shielding body, the first channel region being adjacent to the metal contact; and
an n-pillar providing a second channel region of the n-type channel region and having a second n-type doping concentration that is lower than the first n-type doping concentration in the first channel region, the n-pillar being disposed adjacent to the first channel region, and to the p-pillar.

2. The Schottky rectifier device of claim 1, wherein the p-pillar extends at least half of a distance of the n-type channel region.

3. The Schottky rectifier device of claim 1, wherein the p-type shielding body extends no more than one-third of a distance of the p-pillar.

4. The Schottky rectifier device of claim 1, wherein the p-pillar includes a first region adjacent to the metal contact and having a first p-type doping concentration, and a second region adjacent to the first region and having a second p-type doping concentration lower than the first p-type doping concentration.

5. The Schottky rectifier device of claim 4, wherein the p-type shielding body and the first region of the p-pillar are degenerately doped and provide tunnel contacts to the metal contact.

6. The Schottky rectifier device of claim 1, wherein the p-pillar and the n-pillar are charge balanced, and have average doses of non-compensated acceptors and donors, respectively, that differ by no more than 1×10¹³cm⁻².

7. The Schottky rectifier device of claim 6, further comprising:
a charge unbalanced n-type region forming a third channel region of the n-type channel region, and disposed between the p-pillar, the n-pillar, and the SiC layer.

8. The Schottky rectifier device of claim 1, wherein the first n-type doping concentration of the first channel region is higher than the second n-type doping concentration of the n-pillar by a factor of 1.5 to 5.

9. The Schottky rectifier device of claim 1, wherein the first channel region extends to an approximate distance of the p-type shielding body.

10. The Schottky rectifier device of claim 1, wherein the p-pillar extends an entire distance from the metal contact to the SiC layer.

11. The Schottky rectifier device of claim 1, wherein the n-pillar is disposed at least partially adjacent to the p-type shielding body.

12. A Schottky rectifier device, comprising:
a metal contact;
an n-type SiC substrate;
an epitaxial layer disposed on the n-type SiC substrate;
an array of n-pillars disposed within the epitaxial layer;
n array of p-pillars disposed within the epitaxial layer, each p-pillar of the array of p-pillars being adjacent to an n-pillar of the array of n-pillars;
an array of p-type shielding bodies formed adjacent to the metal contact and having a lateral spacing from the p-pillars; and
n-type channel regions formed within the epitaxial layer and within the lateral spacing, the n-type channel regions having a first n-type doping concentration higher than a second n-type doping concentration of the array of n-pillars.

13. The Schottky rectifier device of claim 12, wherein each p-pillar of the array of p-pillars extends at least half of a distance of the n-type channel region, and each p-type shielding body of the array of p-type shielding bodies extends no more than one-third of a distance of each p-pillar of the array of p-pillars.

14. The Schottky rectifier device of claim 12, wherein the array of p-pillars and the array of n-pillars are charge balanced, and have average doses of non-compensated acceptors and donors, respectively, that differ by no more than 1×10¹³cm⁻².

15. A method of making a Schottky rectifier device, the method comprising:
forming a Silicon Carbide (SiC) substrate layer;
forming an n-type epitaxial region on the SiC substrate;
performing p-type ion implantation to form a p-pillar;
forming an implanted n-type region across a surface of the n-type epitaxial region;
forming a p-type shielding body in the implanted n-type region; and
forming a metal contact on the p-pillar, the n-type region, and the p-type shielding body.

16. The method of claim 15, comprising:
repeating the forming of the epitaxial layer and the masked ion implantation until the p-pillar reaches a specified thickness.

17. The method of claim 15, comprising:
forming the p-pillar to extend at least half of a distance of the n-type epitaxial region.

18. The method of claim 15, comprising:
forming the p-type shielding body to extend no more than one-third of a distance of the p-pillar.

19. The method of claim 15, comprising:
forming a mask layer on the n-type epitaxial region;
performing the p-type ion implantation through the mask layer to form the p-pillar; and
removing the mask layer.

20. The method of claim 15, comprising:
forming the implanted n-type region with an n-type doping concentration that is higher than the n-type epitaxial region by a factor of 1.5 to 5.
